(19) United States
(12) Patent Application Publication
(10) Pub. No.: US 2014/0332779 A1
(43) Pub. Date: Nov. 13, 2014

(54) OLED DEVICE AND MANUFACTURING METHOD THEREOF AND DISPLAY PANEL APPLYING THE SAME

(71) Applicant: EverDisplay Optronics (Shanghai) Limited, Shanghai (CN)

(72) Inventor: Hsin Chih LIN, Shanghai (CN)

(73) Assignee: EverDisplay Optronics (Shanghai) Limited, Shanghai (CN)

(21) Appl. No.: 14/272,843

(22) Filed: May 8, 2014

(30) Foreign Application Priority Data
May 9, 2013 (CN) 201310169995.X

(51) Int. Cl. H01L 27/32; H01L 51/52; H01L 51/56

(52) U.S. Cl. CPC H01L 27/3244; H01L 51/56; H01L 51/5271; H01L 51/5218; H01L 51/5234
USPC 257/40; 438/29

(57) ABSTRACT

An organic light emitting device relates to a WOLED based Top emission organic light emitting device and the manufacturing method thereof and a display panel which applies the organic emitting device. In the organic light emitting device, a plurality of emitting units are formed on a substrate and isolated respectively; a plurality of independent optical adjustment layers are formed between the reflective electrode and the transparent positive electrode of each emitting unit respectively; a color filter layer is formed above the emitting units. This embodiment applies the structure of WOLED into the top emission device, the mask having a maximum aperture ratio in the evaporation process, consequently, it improved yield rate of display panel manufacturing, reduced the costing of the evaporation process and improved the resolution of the display panel.

### CROSS-REFERENCE TO RELATED APPLICATIONS

The present application claims priority to the benefit of Chinese Patent Application No. CN 201310169995.X, filed on May 9, 2013. The entire content of which is incorporated herein by reference.

### BACKGROUND OF THE INVENTION

1. Field of the Invention

The present disclosure relates to the technology of organic light emitting device, more specifically, to a top emission organic light emitting device based on White Organic Light Emitting Diode (“WOLED”, hereinafter), the manufacturing method thereof and a display panel which applies the organic emitting device.

2. Description of the Related Art

High resolution display panel is popular in the market. The Active Matrix Organic Light Emitting Diode (“AMOLED”) is also popular. AMOLED based display panel dominates the market of small-to-medium-size displays, in particular the displays with pixel density of 200 ppi (pixel per inch). AMOLED WVGA, short for Wide Video Graphics Array 800*480 with 200 ppi, having a resolution higher than that of VGA is popular in the market. Reaching for high pixel density, such as 250 ppi, 300 ppi or even 350 ppi, is the target of display panel development. In related art, the AMOLED manufacturing process adopts side-by-side pixel arrangement. Yet, side-by-side pixel arrangement is difficult to be applied to the display panel manufacture process, whose density is 300 ppi or higher. Therefore, another method is used in AMOLED manufacturing process which is based on WOLED device with additional color filter, CF in short. This manufacture method achieves pixel density of 250 ppi to 350 ppi due to applying the metal mask with the maximum aperture ratio in the evaporation process.

The process of applying top emission organic light emitting device is to achieve high pixel density in AMOLED display panel and high aperture ratio of the evaporation mask. The top emission organic light emitting device comprises a positive electrode and a negative electrode. A micro cavity between the positive electrode and the negative electrode is formed consequently. The micro cavity is adjusted for the purposes of the optimum luminous efficiency and high color purity. By adjusting the thickness of the micro cavity, the constructive interference is generated under the preconfigured light wavelength, and consequently, it increases the luminous efficiency and color purity.

The luminescent spectrum of the WOLED covers the range from blue-ray to red-ray. If top emission organic light emitting device applies the structure of WOLED, white light will generate constructive interference and destructive interference in diverse color area of the color filter. WOLED is formed by entire aperture ratio evaporation mask. In the position arrangement of three original colors of Red, Green and Blue, the thickness of each of the three colors is the same. It is not available to adjust the thickness of the film in order to adjust the thickness of the micro cavity. Consequently, it is not available to generate constructive interference under all wavelength of the colorful emitting device, such as RGB emitting device.

Summarily, top emission organic light emitting device cannot overcome the problem of adjusting the micro cavity, consequently, is not available to be applied to the WOLED structure.

### SUMMARY OF THE INVENTION

An aspect of the embodiment of a preferred embodiment of the present disclosure is directed toward an organic light emitting device for applying the structure of WOLED into top emission device, the entire aperture ratio mask in the evaporation process.

Another aspect of one embodiment a preferred embodiment of the present disclosure is directed toward a manufacturing method for improving yield rate of display panel, reducing the cost of the evaporation process, and resolution of the display panel.

An embodiment of the present disclosure provides an organic light emitting device, comprising:

a plurality of emitting units separated from each other and formed on a substrate;

a reflective electrode formed on the substrate to upwardly reflect lights;

a color filter layer formed above the emitting units and consisting of several color areas corresponding to the emitting units for forming color channels of a preconfigured color system;

wherein, each emitting unit comprises a WOLED layer, and an independent optical adjustment layers served to adjust wave-length of the light emitted by the WOLED layer are formed between the WOLED layer and the reflective electrode.

According to one embodiment of the present disclosure, wherein each emitting unit further comprises a semi-reflective negative electrode and a transparent electrode, and the WOLED layer is between the semi-reflective negative electrode and the transparent electrode.

According to one embodiment of the present disclosure, wherein each color channel of the preconfigured color system is formed by an emitting light which is emitted from one of the emitting units and is passing through the corresponding color area.

According to one embodiment of the present disclosure, wherein there are three emitting units formed on the substrate.

According to one embodiment of the present disclosure, wherein the color filter layer consists of three color areas which are red-ray area, blue-ray area and green ray area.

According to one embodiment of the present disclosure, wherein the reflective electrode is made of silver or aluminum.

According to one embodiment of the present disclosure, wherein the Semi-reflective negative electrode is made of magnesium or silver or magnesium-silver alloy.

Another embodiment of the present disclosure provides a manufacturing method of organic light emitting device, comprising:

(a) forming a reflective electrode layer on a substrate;

(b) forming several optical adjustment layers separated from each other on the reflective electrode layer, and the number of the optical adjustment layers is identical with the number of the emitting units;

(c) forming a transparent electrode layer on the optical adjustment layer of each emitting unit;

(d) forming a WOLED layer on the transparent electrode layer of each emitting unit;

(e) forming a semi-reflective negative electrode layer on the WOLED layer of each emitting unit; and

(f) packaging the device formed in Step (e), and forming the color filter layer by means of sealing the top surface of the device with the color filters having preconfigured color areas.

According to another embodiment of the present disclosure, wherein the steps of forming the optical adjustment layers in step (b) comprises:

forming an optical adjustment layer integrally by means of PVD process or CVD process or CBD process; and

patterning the optical adjustment layer by photoetching process and etching process, which divides the adjustment layer into several parts separated from each other;

wherein, the thickness of the optical adjustment layer of the different emitting unit is not identical.

According to another embodiment of the present disclosure, wherein the formation of WOLED layers in Step (d) comprises:

unifying the thickness of the WOLED layer of each emitting unit by performing the evaporation process using the metal mask having a maximum aperture ratio.

According to another embodiment of the present disclosure, wherein the formation of semi-reflective negative electrode layers in Step (e) comprises:

unifying the thickness of the semi-reflective negative electrode layer of each emitting unit by performing the evaporation process using the metal mask having a maximum aperture ratio.

According to another embodiment of the present disclosure, wherein the packaging of the device in Step (f) comprises:

performing the thin film encapsulation process with inorganic coating or inorganic water-resistive coating;

performing the cofferdam process and the filling process;

completing the packaging by gluing the substrate to a backboard having color filters.

Another embodiment of the present disclosure provides a display panel, wherein the display panel mainly consists of the organic light emitting device as claimed in claim 1.

According to another embodiment of the present disclosure, wherein there are three emitting units formed on the substrate.

According to another embodiment of the present disclosure, wherein the color filter layer consists of three color areas which are red-ray area, blue-ray area and green ray area.

According to another embodiment of the present disclosure, wherein the reflective electrode is made of silver or aluminum.

### BRIEF DESCRIPTIONS OF THE DRAWINGS

Those skilled in the art will appreciate the improvements and advantages that derive from the present invention upon reading the following detailed description, claims, and drawings, in which:

FIG. 1 shows the structure diagram of the organic light emitting device having three emitting units achieving RGB color system in the embodiment according to the present disclosure;

FIG. 2 shows the tabulation of the relations of several kinds of common materials and thickness thereof in the embodiment of RGB color system achieved by the organic light emitting device according to the present disclosure;

FIG. 3 shows the flow diagram of the manufacturing method in the embodiment according to the present disclosure.

### DETAILED DESCRIPTIONS

The present disclosure will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the term “plurality” means a number greater than one.

Hereinafter, certain exemplary embodiments according to the present disclosure will be described with reference to the accompanying drawings.

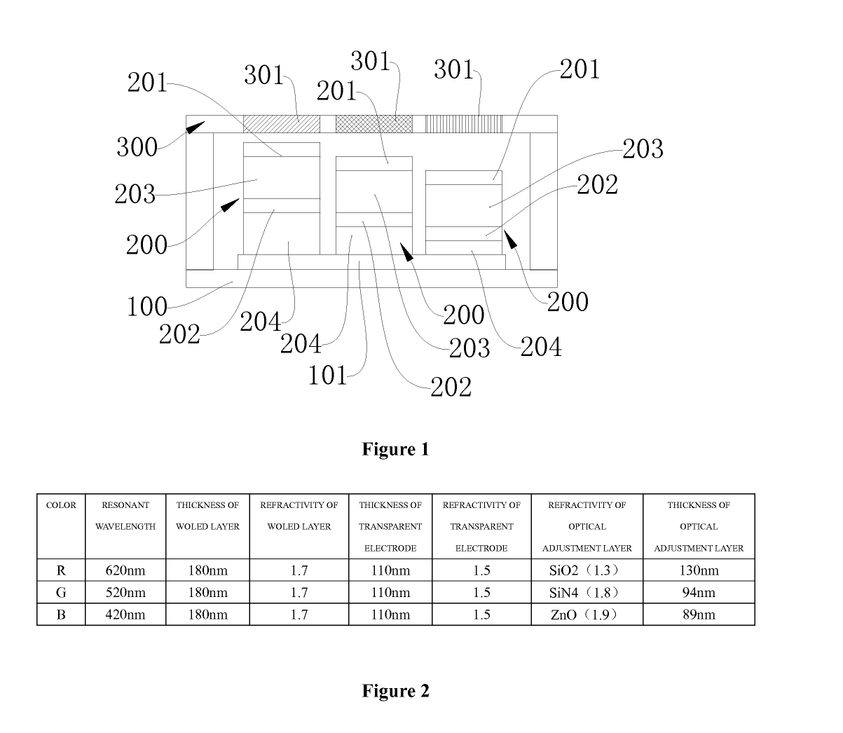

An embodiment according to the present invention comprises an organic light emitting device, as shown in FIG. 1, wherein the organic light emitting device comprises a plurality of Emitting Units 200 separated from each other and formed on a Substrate 100. Each Emitting Unit 200 comprises a Semi-reflective Negative Electrode 201, a Transparent Electrode 202 and a WOLED Layer 203 which was formed between Semi-reflective Negative Electrode 201 and Transparent Electrode 202.

A Reflective Electrode 101 is formed on Substrate 100 and is shared by lots of Emitting Units 200, and is used for upward reflecting the emitting light emitted form Emitting Units 200. A plurality of the independent Optical Adjustment Layers 204 is formed between the Reflective Electrode 101 and Transparent Electrode 202 of each Emitting Unit 200 respectively. Optical Adjustment Layer 204 is served to adjust the wave-length of the emitting light emitted by WOLED Layer 203.

A Color Filter Layer 300 is formed above Emitting Units 200. Color Filter Layer 300 is divided into several Color Areas 301, and each Color Area 301 is corresponded to an Emitting Unit 200. A color channel of a preconfigured color system is formed by the emitting light emitted from one of Emitting Unit 200 coordinated with the corresponding Color Area 301 and passing through Color Area 301.

Above-mentioned solution forms a top emission organic light emitting device by means of a plurality of the independence Emitting Units 200 based on WOLED, and sets up independence Optical Adjustment Layer 204 corresponding to each Emitting Unit 200 between them and Reflective Electrode 101 shared by them. Consequently, it is available to adjust the thickness of Optical Adjustment Layer 204 of each Emitting Unit 200 separately in the manufacture process. Further, the emitting light of each Emitting Unit 200 meets the requirement of constructive interference where the wavelength of emitting light of each color channel is adjusted separately in Optical Adjustment Layer 204 as micro cavity between Reflective Electrode 101 and Semi-reflective Negative Electrode 201 of each Emitting Unit 200.

Above-mentioned solution may apply into RGB color system by setting up three Emitting Units 200 and setting up three Color Areas 301 in Color Filter 300. Three color channels are formed by Color Areas 301 coordinating with the corresponding emitting unit respectively. The three channels are red-ray channel, blue-ray channel and green-ray channel. Meanwhile, above-mentioned solution adopts RGB color system, and further adopts any other color system consists of multiple color channels.

Preferably, Reflective Electrode 101 is made of metal with high reflectance; in particular it is made of silver or aluminum.

Preferably, Semi-reflective Negative Electrode 201 is made of Semi-reflective thin metal layer; in particular it is made of magnesium or silver or magnesium-silver alloy.

Preferably, Optical Adjustment Layer 204 is made of organics or inorganics or chemical compound. The thickness of Optical Adjustment Layer 204 changes depending on divers material by which the Optical Adjustment Layer is made of. It can be calculated by the formulas listed below:

$$\begin{matrix}\begin{matrix}\frac{2 L}{λ} - \frac{Φ}{2 π} = m & ( m = 1 , 2 , 3 , 4 … Integer )\end{matrix} & ( 1 ) \\ L = \sum {n}_{i} {l}_{i} & ( 2 ) \\ Φ = {Φ}_{1} + {Φ}_{2} & ( 3 ) \\ {Φ}_{1} = {tan}^{- 1} \frac{2 {n}_{a} {k}_{1}}{{n}_{a}^{2} - {n}_{1}^{2} - {k}_{1}^{2}} & ( 4 ) \\ {Φ}_{2} = {tan}^{- 1} \frac{2 {n}_{b} {k}_{2}}{{n}_{b}^{2} - {n}_{2}^{2} - {k}_{2}^{2}} & ( 5 )\end{matrix}$$

Wherein, L refers to the optical length from Reflective Electrode 101 to Semi-reflective Negative Electrode 201 of Emitting Unit 200; λ refers to resonant wavelength; nᵢ refers to refractivity of divers material; lᵢ refers to the thickness of each layers; φ refers to the summation of metal phase difference form Reflective Electrode 101 to Semi-reflective Negative Electrode 201; φ₁ refers to the metal phase difference of Semi-reflective Negative Electrode 201; φ₂ refers to the metal phase difference of Reflective Electrode 101; nₐ refers to the refractivity of the part which is closed to Semi-reflective Negative Electrode 201 of Optical Adjustment Layer 204; n₁ refers to the real part of the refractivity of Semi-reflective Negative Electrode 201; k₁ refers to the imaginary part of the refractivity of Semi-reflective Negative Electrode 201; n_{b} refers to the refractivity of the part which is closed to Reflective Electrode 101 of Optical Adjustment Layer 204; n₂ refers to the real part of the refractivity of Reflective Electrode 101; k₂ refers to the imaginary part of the refractivity of Reflective Electrode 101.

When nₐ, n_{b}, n₁, n₂, k₁, and k₂ are all known constants, L is the summation of the optical length of WOLED Layer 203 plus optical length of Transparent Electrode 202 and plus optical length of Optical Adjustment Layer 204. WOLED Layer 203 has the same optical length in each Emitting Unit 200, and, so does Transparent Electrode 202. Therefore, in the case of RGB color system, after the wavelength (λᵣ, λ_{g}, λ_{b}) were selected, the optical length of Optical Adjustment Layers 204 which are corresponded to RGB Emitting Units 200 can be calculated by the formulas above-mentioned. If the refractivity of Optical Adjustment Layers 204 were foregone, then the optimum thickness of the Optical Adjustment Layers 204 which are corresponded to RGB Emitting Units 200 can be acquired.

Preferably, the formula (1) can be simplified as following by ignoring the metal phase difference:

$$\begin{matrix}L = m \frac{λ}{2} & ( L is an integral multiple of \frac{λ}{2} )\end{matrix} \qquad ( 6 )$$

The relations of several kinds of common material and thickness thereof calculated by the formula (6) are shown in FIG. 2.

The optical length of Optical Adjustment Layer 204 which is required can be calculated by the formula with the selected resonant wavelength. In the case of the optical length of Optical Adjustment Layer 204 known, the optical length L of Optical Adjustment Layer 204 should be equal to the product of refractivity of the material, multiples lᵢ, the thickness of Optical Adjustment Layer 204, when Optical Adjustment Layer 204 is made with divers materials. The resonant wavelength can be acquired, only if the condition above mentioned is met. Therefore, it is necessary to calculate the thickness of Optical Adjustment Layer 204 by the formula (7) with the refractive index of the selected material as well as the optical length of Optical Adjustment Layer 204.

L=nᵢlᵢ (7)

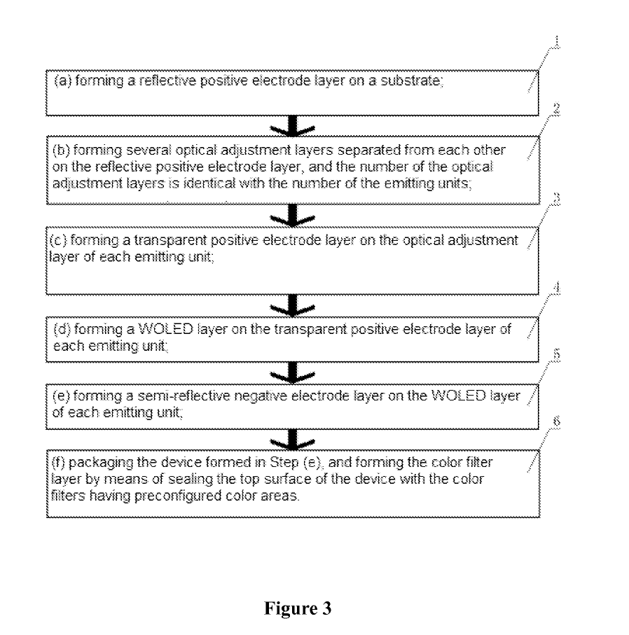

The embodiment according to the present invention also comprises a manufacturing method of organic light emitting device, wherein, the method is applied in manufacturing the organic light emitting device above mentioned, as shown in FIG. 3, the method includes the following steps:

Step 1, forming a reflective positive electrode layer on a substrate;

Step 2, forming several optical adjustment layers separated from each other on the reflective positive electrode layer, and the number of the optical adjustment layers is corresponded to the number of the emitting units;

Step 3, forming a transparent positive electrode layer on the optical adjustment layer of each emitting unit;

Step 4, forming a WOLED layer on the transparent positive electrode layer of each emitting unit;

Step 5, forming a semi-reflective negative electrode layer on the WOLED layer of each emitting unit;

Step 6, packaging the device formed in Step (e), and forming the color filter layer by means of sealing the top surface of the device with the color filters having preconfigured color areas.

Preferably, the steps of forming the optical adjustment layers in Step 2 comprises: forming an optical adjustment layer integrally by means of PVD (physical vapor deposition) or CVD (chemical vapor deposition) or CBD (chemical bath deposition); patterning the optical adjustment layer by photoetching process and etching process, which divides the adjustment layer into several parts separated from each other; and having the divers optical adjustment layers which were corresponded to divers emitting units with the different preconfigured thickness. The thickness of the optical adjustment layer may be calculated, according to the required wavelength and the relationship between the material and the thickness of the optical adjustment layer, which was expounded in the technical solution of the organic light emitting device above-mentioned.

Preferably, the formation of WOLED layers in Step 4 comprises: unifying the thickness of the WOLED layer of each emitting unit by performing the evaporation process using the metal mask having a maximum aperture ratio. Due to application of the maximum aperture ratio metal mask, the possibility of blemish arising can be decreased effectively, and the cost of the process can be reduced, and the possibility of the further improvement of the display panel in resolution is provided.

Preferably, the formation of semi-reflective negative electrode layers in Step 5 comprises: unifying the thickness of the semi-reflective negative electrode layer of each emitting unit by performing the evaporation process using the metal mask having a maximum aperture ratio. It is easy to discover that all of the evaporation process above-mentioned can be performed with the metal mask having a maximum aperture ratio, so that the yield rate of the integral process will be improved absolutely.

Preferably, the packaging of the device in Step 6 comprises: firstly, performing the thin film encapsulation process with inorganic coating or inorganic water-resistive coating; and then, performing the cofferdam process and the filling process; finally, completing the packaging by gluing the substrate to a backboard having color filters.

The embodiment according to the present invention further comprises a display panel, wherein, the display panel mainly consists of the Organic Light Emitting Device above mentioned.

The foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

What is claimed is:

1. An organic light emitting device, comprising:
a plurality of emitting units separated from each other and formed on a substrate;
a reflective electrode formed on the substrate to upwardly reflect lights;
a color filter layer formed above the emitting units and consisting of several color areas corresponding to the emitting units for forming color channels of a preconfigured color system;
wherein, each emitting unit comprises a WOLED layer, and an independent optical adjustment layers served to adjust wave-length of the light emitted by the WOLED layer are formed between the WOLED layer and the reflective electrode.

2. The organic light emitting device as claimed in claim 1, wherein each emitting unit further comprises a semi-reflective negative electrode and a transparent electrode, and the WOLED layer is between the semi-reflective negative electrode and the transparent electrode.

3. The organic light emitting device as claimed in claim 2, wherein each color channel of the preconfigured color system is formed by an emitting light which is emitted from one of the emitting units and is passing through the corresponding color area.

4. The organic light emitting device as claimed in claim 3, wherein there are three emitting units formed on the substrate.

5. The organic light emitting device as claimed in claim 4, wherein the color filter layer consists of three color areas which are red-ray area, blue-ray area and green ray area.

6. The organic light emitting device as claimed in claim 1, wherein the reflective electrode is made of silver or aluminum.

7. The organic light emitting device as claimed in claim 2, wherein the Semi-reflective negative electrode is made of magnesium or silver or magnesium-silver alloy.

8. A manufacturing method of organic light emitting device, comprising:
(a) forming a reflective electrode layer on a substrate;
(b) forming several optical adjustment layers separated from each other on the reflective electrode layer, and the number of the optical adjustment layers is identical with the number of the emitting units;
(c) forming a transparent electrode layer on the optical adjustment layer of each emitting unit;
(d) forming a WOLED layer on the transparent electrode layer of each emitting unit;
(e) forming a semi-reflective negative electrode layer on the WOLED layer of each emitting unit; and
(f) packaging the device formed in Step (e), and forming the color filter layer by means of sealing the top surface of the device with the color filters having preconfigured color areas.

9. The manufacturing method of organic light emitting device as claimed in claim 8, wherein the steps of forming the optical adjustment layers in step (b) comprises:
forming an optical adjustment layer integrally by means of PVD process or CVD process or CBD process; and
patterning the optical adjustment layer by photoetching process and etching process, which divides the adjustment layer into several parts separated from each other;
wherein, the thickness of the optical adjustment layer of the different emitting unit is not identical.

10. The manufacturing method of organic light emitting device as claimed in claim 8, wherein the formation of WOLED layers in Step (d) comprises:
unifying the thickness of the WOLED layer of each emitting unit by performing the evaporation process using the metal mask having a maximum aperture ratio.

11. The manufacturing method of organic light emitting device as claimed in claim 8, wherein the formation of semi-reflective negative electrode layers in Step (e) comprises:
unifying the thickness of the semi-reflective negative electrode layer of each emitting unit by performing the evaporation process using the metal mask having a maximum aperture ratio.

12. The manufacturing method of organic light emitting device as claimed in claim 8, wherein the packaging of the device in Step (f) comprises:
performing the thin film encapsulation process with inorganic coating or inorganic water-resistive coating;
performing the cofferdam process and the filling process;
completing the packaging by gluing the substrate to a backboard having color filters.

13. A display panel, wherein the display panel mainly consists of the organic light emitting device as claimed in claim 1.

14. The display panel as claimed in claim 13, wherein there are three emitting units formed on the substrate.

15. The display panel as claimed in claim 13, wherein the color filter layer consists of three color areas which are red-ray area, blue-ray area and green ray area.

16. The display panel as claimed in claim 13, wherein the reflective electrode is made of silver or aluminum.
